(19) United States
(12) Patent Application Publication
(10) Pub. No.: US 2003/0205759 A1
(43) Pub. Date: Nov. 6, 2003

(54) Reduction of parasitic bipolar leakage current in silicon on insulator devices

(75) Inventors: Todd Alan Christensen, Rochester, MN (US); David Michael Friend, Rochester, MN (US); Nghia Van Phan, Rochester, MN (US); John Edward Sheets II, Zumbrota, MN (US)

Correspondence Address: Gero G. McClellan, Moser, Patterson & Sheridan, L.L.P., Suite 1500, 3040 Post Oak Boulevard, Houston, TX, 77056-6582, US

(73) Assignee: International Business Machines Corporation, Armonk, NY

(21) Appl. No.: 10/003,942

(22) Filed: Oct. 23, 2001

(51) Int. Cl. H01L 27/01

(52) U.S. Cl. 257/347

(57) ABSTRACT

A method and apparatus for reducing parasitic bipolar transistor leakage current in a Silicon on Insulator (SOI) Metal Oxide Semiconductor (MOS). A capacitor is operatively coupled between the base and emitter terminals of the parasitic bipolar transistor. The capacitor effectively reduces the base to emitter voltage of the parasitic transistor thereby reducing leakage current generated at the collector terminal.

### BACKGROUND OF THE INVENTION

1. Field of the Invention

The present invention generally relates to a method and apparatus for reducing parasitic bipolar leakage current in silicon-on-insulator (SOI) devices. More specifically, the invention relates to reducing the effect of bipolar leakage current on SOI field effect transistors (FET) in digital logic circuits.

2. Description of the Related Art

In recent years, Metal Oxide Semiconductor (MOS) Field Effect Transistors (FET) integrated circuits and Complementary Metal Oxide Semiconductor (CMOS) FET's have gained popularity and are the most widely used type of integrated circuit technology. Today, CMOS electronic devices provide advantages of higher operating speeds, smaller size, lower power consumption, and are increasingly becoming cheaper to manufacture as a result of smaller component size, higher manufacturing production yields per semiconductor wafer, and larger wafer sizes. The most popular integrated circuit devices manufactured using CMOS technology are microprocessors, memory and digital logic circuits. Conventional MOS and CMOS devices consist of poly-silicon on an oxide layer that is placed on a silicon substrate. The added impurities in the silicon substrate enable these devices to operate as transistors.

Silicon-on-insulator (SOI) technology is an enhanced silicon technology currently being utilized to increase the performance of CMOS devices. SOI semiconductors include a thin layer of silicon placed on top of an insulator, such as silicon oxide or glass, and a MOS transistor built on top of this structure. Using SOI technology, designers can increase the speed of digital logic integrated circuits while reducing their overall power consumption. These advances in technology will lead to the development of more complex and faster computer integrated circuits that operate with less power.

The main advantage of constructing the MOS transistor on top of an insulator layer is to reduce the internal capacitance of the transistor. This is accomplished by placing the insulator oxide layer between the silicon substrate and the impurities required for the device to operate as a transistor. Reducing the internal capacitance of the transistor increases its operating speed. Therefore, with SOI technology, faster MOS transistors can be manufactured resulting in higher performance semiconductors to fuel emerging needs for faster electronic devices.

SOI technology has several drawbacks. An inherent drawback of placing a MOS transistor on top of an SOI layer is that the MOS transistor is actually placed in parallel with a bipolar junction transistor. The parallel bipolar junction transistor is an undesirable product of the SOI manufacturing process. If enough current is placed through the MOS transistor, the parasitic bipolar transistor will turn on. This causes an unwanted effect called bipolar discharge and lowers the performance of the MOS transistor.

FIG. 1 illustrates a cross sectional view of a silicon-on-insulator (SOI) metal oxide semiconductor (MOS) n-type field effect transistor (NFET) 100. Illustratively, NFET 100 is built on an insulator 110 such as silicon dioxide.

In SOI devices, the body 104 of the NFET 100, or base region of the parasitic bipolar transistor, which lies beneath the gate 112 of the NFET 100, is floating. The body 104 of the transistor can become charged to a high potential by junction 102 leakage induced whenever both the drain 106 and source 108 terminals are at a high potential. In this illustration, the drain 106 of the NFET 100 is the collector region of the parasitic bipolar transistor and the source 108 is the emitter region of the parasitic bipolar transistor.

If the body 104 of the NFET 100 charges to a high potential and the source 108 is pulled to a low potential, the trapped charge in the body 104, or base region, becomes available as a parasitic base current. If the parasitic base current is of sufficient magnitude, it will activate the parasitic bipolar transistor and thus generate a collector current at the drain 106. The collector current, flowing in parallel with the drain 106 current, is undesirable as it causes a loss of charge at the drain 106.

FIG. 2 illustrates an equivalent circuit schematic 200 of an SOI NFET 206 and the parallel parasitic bipolar NPN transistor 208. The body terminal 212 of the NFET 206 is equivalent to the base terminal 220 of the parasitic bipolar transistor 208 and is located at the body 212 of NFET 206. The drain 214 of NFET 206 is equivalent to the collector 216 of the parasitic bipolar transistor 208. The body 212 of NFET 206 becomes charged by induced leakage whenever the drain 214 and source 218 terminals are held at a high potential approaching VDD. If the source 218 is dropped to a low potential, the trapped charge in the body 212 causes a current to flow into the base 220 of the parasitic bipolar transistor 208. This causes a current to flow in the collector 216 that is parallel to a current flowing in the drain 214. This action discharges the drain 214 node of a digital logic circuit.

Normally, parasitic bipolar action does not manifest itself in conventional MOS transistors because the base of the bipolar transistor is always kept at ground potential, keeping the bipolar transistor in an off state. In SOI, the body of the MOS FET device, or base of the bipolar transistor, is floating and can be charged high by junction leakages induced when the drain and source terminals of the MOS FET are at a high potential. Subsequently, if the source is pulled to a low potential, the trapped charge in the base area is available as parasitic current. The parasitic base current activates the bipolar transistor and generates a collector current at the drain terminal of the MOS FET. The unintentional loss of charge could lead to system failure, for example, by erroneously switching logic state in a digital logic circuit.

FIG. 3 is a schematic diagram of a typical SOI CMOS (complementary metal oxide semiconductor) digital logic circuit 300 illustrating the effects of parasitic bipolar transistor leakage current on the circuit. Pass-gate transistor N1 302 is in its “off” state when its gate is at ground potential. Pass-gate transistor P1 304 is in its “off” state when its gate is at the supply voltage (VDD). If nodes “A” 306 and “B” 308 are equal to VDD (thereby putting the source 310 and drain 312 terminals of N1 302 at a high potential), the base 314 of parasitic transistor T1 316 will become charged. If node “A” 306 is then switched from VDD to ground potential, T1 316 will become activated causing leakage current to flow from its collector 318 to the drain 312 of N1 302. This leakage current flowing to the drain 312 of N1 302 may cause N1 302 to undesirably change logic states. The same effect is realized on P1 304 by parasitic transistor T2 if node “A” 306 is then switched from ground to VDD.

Therefore, there is a need for a method and apparatus that reduces parasitic bipolar action to eliminate parasitic current in an SOI FET device.

### SUMMARY OF THE INVENTION

The present invention generally provides a method and apparatus for reducing parasitic bipolar transistor current in silicon-on-insulator metal oxide semiconductor devices.

In one embodiment, a method is provided for operatively coupling a capacitor in parallel to the base and emitter nodes of a parasitic bipolar transistor in a silicon-on-insulator (SOI) metal oxide semiconductor device (MOS). The capacitor may be an external capacitor coupled to the base and emitter nodes of the parasitic transistor or may be incorporated within the SOI MOS device.

In another embodiment, a method is provided for forming a capacitor by increasing the doping concentration of the source/drain diffusion and the body doping of the SOI MOS device.

In another embodiment, a method is provided for forming a capacitor by increasing the area of the source/drain to body diffusion of the SOI MOS device.

In still another embodiment, a circuit is provided for coupling a capacitor in parallel with the base and emitter nodes of a parasitic bipolar transistor in an SOI MOS device. The capacitor having a first and second terminal wherein the first terminal is coupled to the base of the parasitic transistor and the second terminal is coupled to the emitter of the parasitic transistor.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 illustrates a cross sectional view of a silicon-on-insulator (SOI) negative field effect transistor (NFET) and a parasitic bipolar transistor.

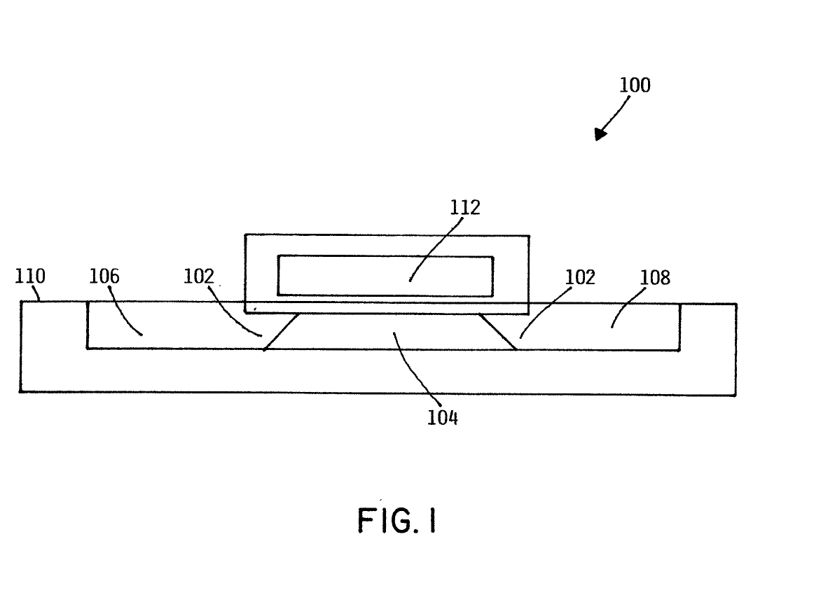

FIG. 2 illustrates an equivalent schematic diagram of an SOI NFET and the parallel parasitic bipolar NPN transistor.

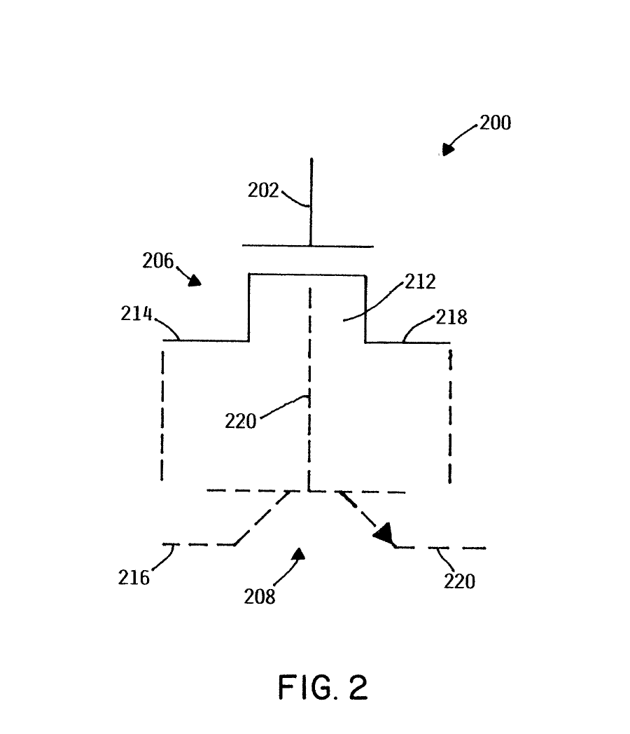

FIG. 3 illustrates an SOI logic circuit.

FIG. 4 illustrates an embodiment of the invention.

FIG. 5 shows a plot of emitter current of a parasitic bipolar transistor.

FIG. 6 shows a plot of base to emitter voltage of a parasitic bipolar transistor.

FIG. 7 illustrates a comparative process of manufacturing of a conventional SOI device and an inventive SOI device wherein a photo-resist mask is applied to the SOI devices.

FIG. 8 illustrates a comparative process of manufacturing of a conventional SOI device and an inventive SOI device wherein an n++ implant is applied to the SOI devices.

FIG. 9 illustrates a comparative process of manufacturing of a conventional SOI device and an inventive SOI device wherein an angular implant of the inventive SOI device is performed.

FIG. 10 illustrates a comparative process of manufacturing of a conventional SOI device and an inventive SOI device wherein the inventive SOI device has increased source/drain to body capacitance.

### DETAILED DESCRIPTION OF THE PREFERRED EMBODIMENTS

The present invention provides a method and apparatus for reducing parasitic bipolar transistor current in silicon-on-insulator field effect transistors. A capacitor is placed in parallel to the base and emitter nodes of the parasitic bipolar transistor to provide AC coupling between the nodes. This AC coupling reduces the base to emitter voltage of the parasitic transistor thereby reducing emitter to collector current.

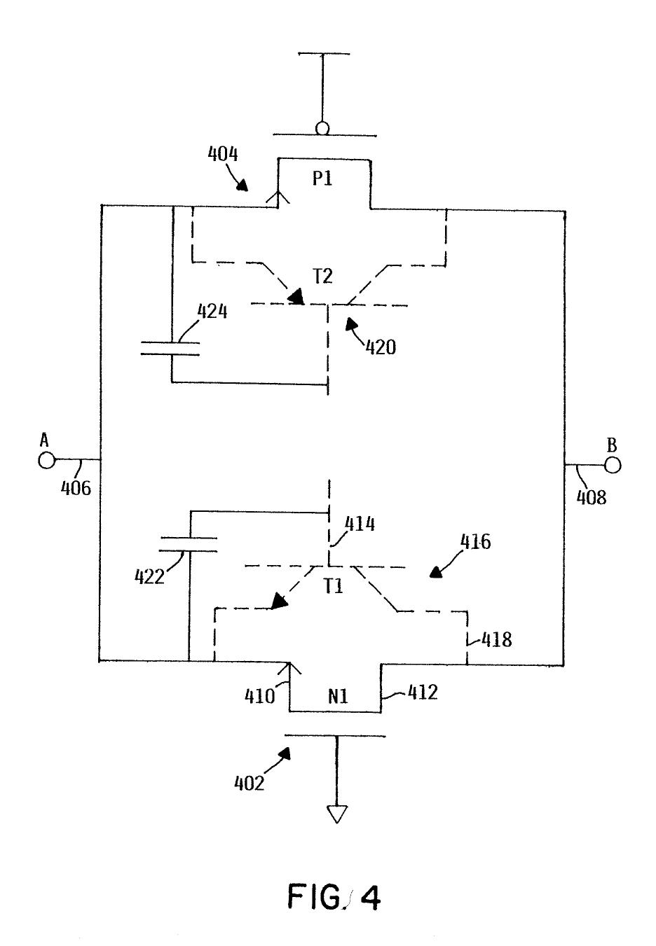

FIG. 4 is a schematic diagram of a digital logic circuit 400 illustrating one embodiment of the invention. Capacitors C1 422 and C2 424 are coupled to the base 414 and emitter 426 nodes of parasitic bipolar transistors T1 and T2 respectively. Capacitors C1 422 and C2 424 act as an AC coupling between the base and emitter nodes of the parasitic bipolar transistors to reduce the base to emitter voltage (Vbe). A reduced Vbe in parasitic transistor T1416 results in a lower leakage current generated at the collector terminal 418. For a typical bipolar transistor, every 20 millivolt (mv) reduction in Vbe results in approximately a two times reduction in collector current. Illustratively, capacitors C1 422 and C2 424 may be any value of capacitance that effectively reduces leakage current generated at the collector terminal 418. By way of illustration and not by limitation, the value of capacitance for C1 422 and C2 424 is two femto farads (fF) and the device length is 2 μm. More generally, the capacitance may be between about 0.5 fF/1 μm to about 4 fF/1 μm.

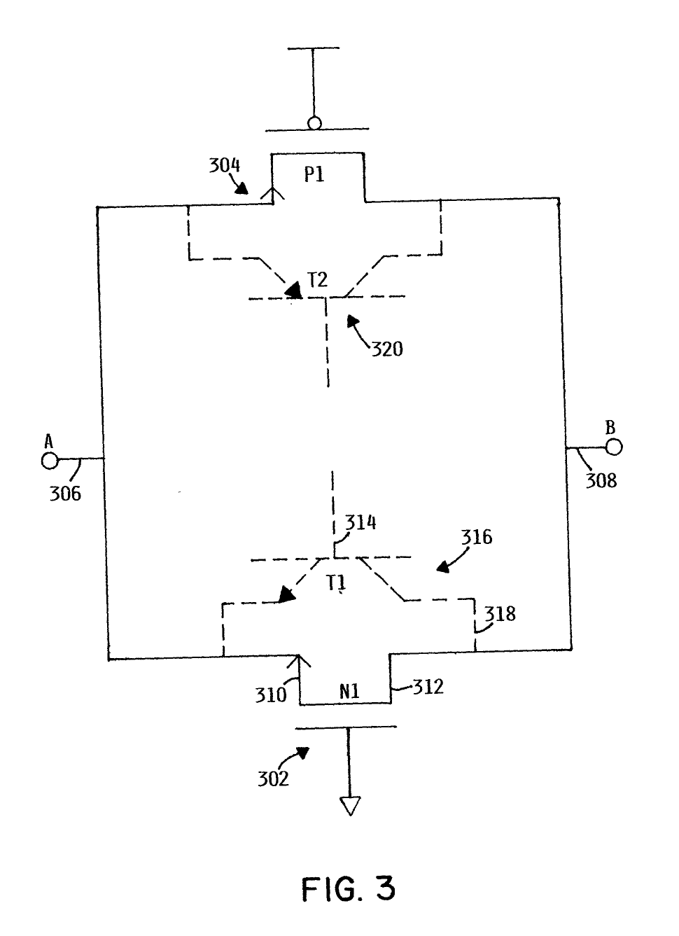

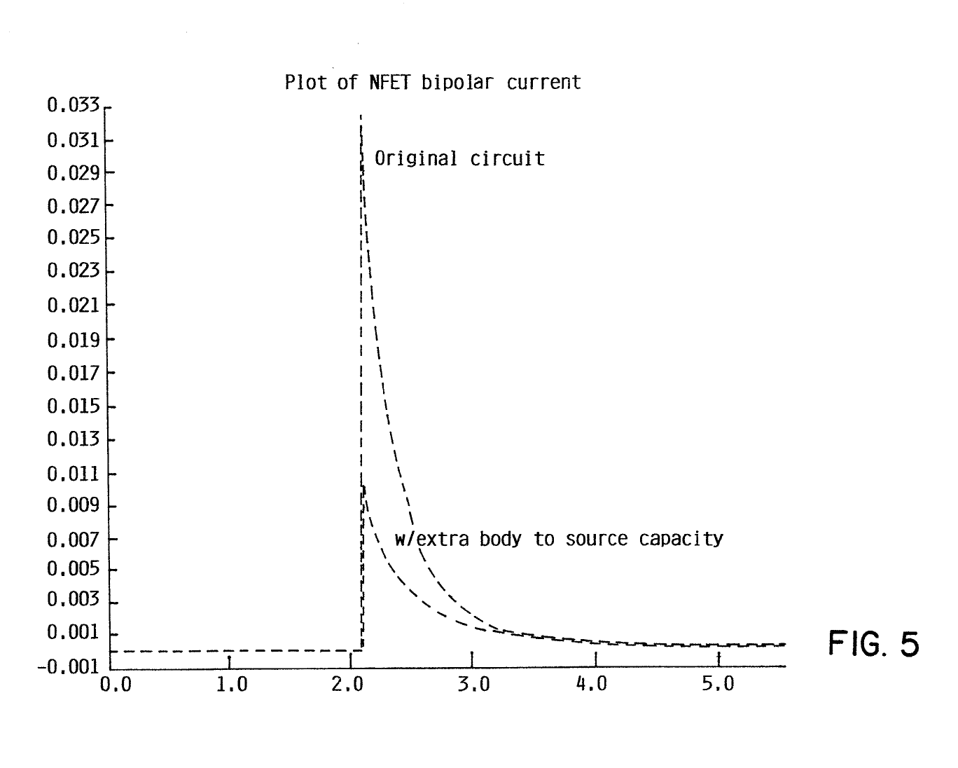

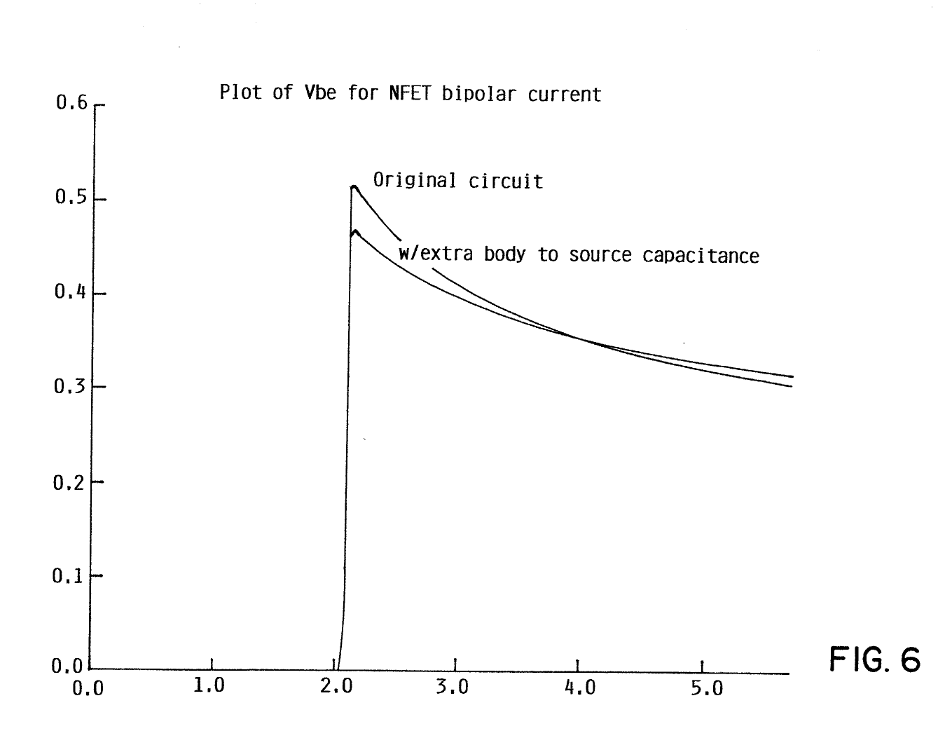

FIG. 5 illustrates a graph plotting the collector current of T1 416. The graph shows a plot trace with and without capacitor C1 422 coupled between the base 414 and emitter 426 terminals of T1 416. With reference to FIGS. 3 and 4, at a time prior to time=two nanoseconds the source 410 and drain 412 of N1 402 are at VDD causing the base 414 of T1 416 to become charged. At time=two nanoseconds, node “A” 406 switches to ground potential causing T1 416 to become activated. Shortly thereafter, inrush leakage current begins to flow from the collector 418 of T1 416 and to the drain 412 terminal of N1 402. According to the graph, there is a thirty-percent reduction in inrush current flowing at the collector 418 of T1 416 when capacitor C1 422 is coupled between its base 414 and emitter 426 terminals. Without capacitor C1 422 installed, the high inrush leakage current present at the drain 412 of N1 from T1 416 can cause N1 402 to erroneously change logical states. FIG. 6 illustrates a corresponding plot of Vbe for T1 416 showing a plot with and without C1 422 installed. At time=two nanoseconds, the base of the parasitic transistor 412 becomes charged. According to the graph, this charge is greatly reduced when capacitor C1 422 is coupled between its base 414 and emitter 426 terminals.

In one embodiment, capacitors C1 422 and C2 420 may be any self-contained capacitor physically coupled between the base and emitter nodes of a parasitic bipolar transistor. Illustratively, these capacitors may be installed during the manufacturing process of the silicon-on-insulator transistor logic device.

In another embodiment, the electrical capacitance of C1 422 or C2 420 may be incorporated within the SOI field effect transistor. Illustratively, this is accomplished by constructing a FET with a larger source/drain to body capacitance. This source/drain to body capacitance would effectively be coupled in parallel to the base and emitter nodes of the parasitic bipolar transistor. As an illustration, either increasing the area of the source/drain to body diffusion or increasing the doping concentration of the source/drain diffusion and the body doping can increase this capacitance. The former process is preferred because it is undesirable to increase the doping concentrations of the source/drain and body diffusions due to reliability constraints and threshold voltage tailoring of the SOI device.

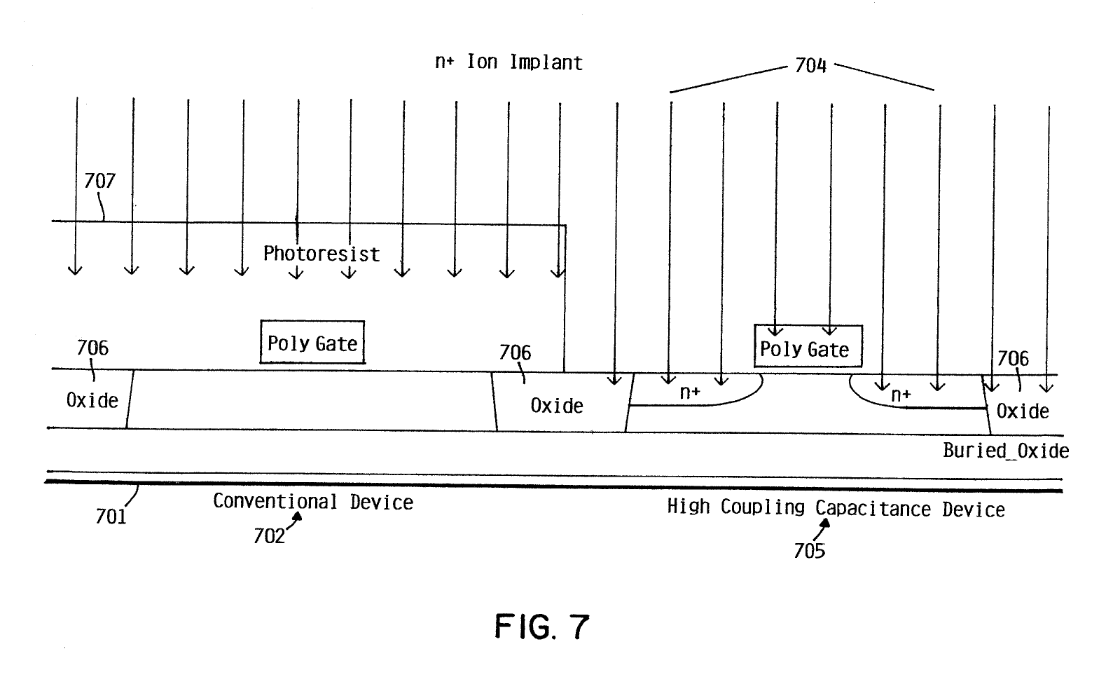

Illustratively, construction of an SOI MOS device with a larger source/drain to body diffusion that results in increased source/drain to body capacitance of a FET is shown in FIGS. 7-10. A left-hand portion of FIGS. 7-10 shows a conventional device. For purposes of comparison, the right-hand portion shows an inventive device manufactured according to the methods described herein. Both devices are manufactured on a wafer formed on a silicon wafer 701. Referring first to FIG. 7, a conventional device 702 is built using the conventional SOI process, known in the art, through poly-silicon gate definition. A photo-resist mask 707 is patterned to block the conventional device 702 while a shallow ion implant 704 is performed on the inventive device 705. Although this example shows construction of a n-type field effect transistor (NFET) using n+ ion implants, a p-type field effect transistor (PFET) may similarly be constructed using p+ ion implants. The photo-resist 707 is then removed and a conventional space oxide 706 is conformably deposited and anisotropically etched to create spacers of oxide (not shown) on the poly-silicon gate sidewalls on both devices 702 and 705.

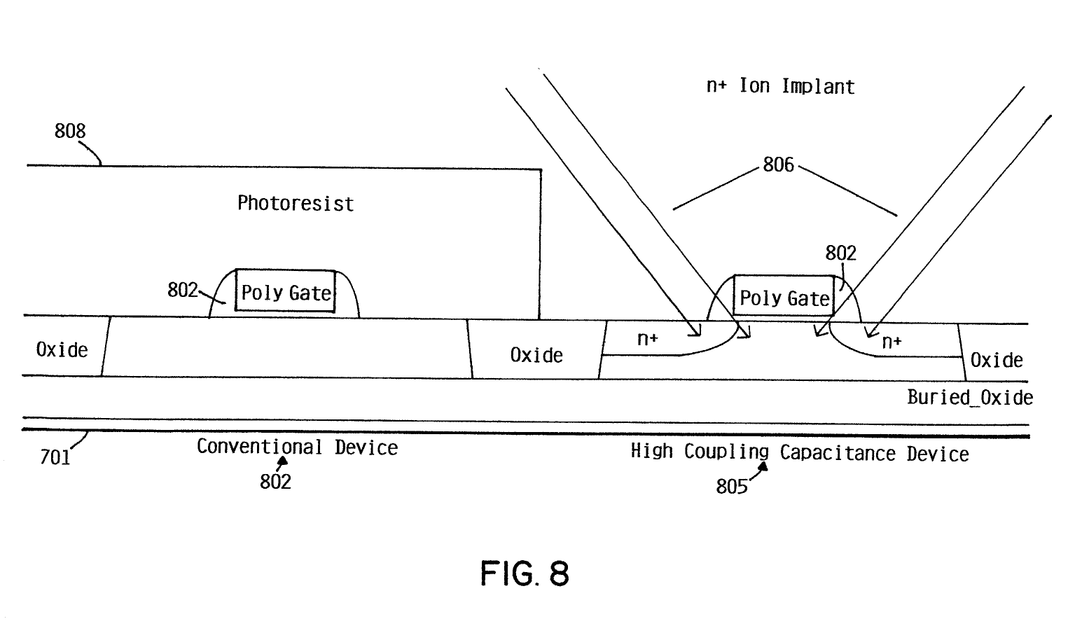

FIG. 8 shows an alternative embodiment for performing an initial n+ ion implant. A conventional space oxide 802 is first formed on both devices 804 and 805 in a manner known in the art. The conventional device 804 is then masked off with photo-resist 807 while performing an angled n+ implant 806 on the inventive device 805. The wafer 701 is rotated to evenly implant the dopant under the gate terminal of the inventive device 805.

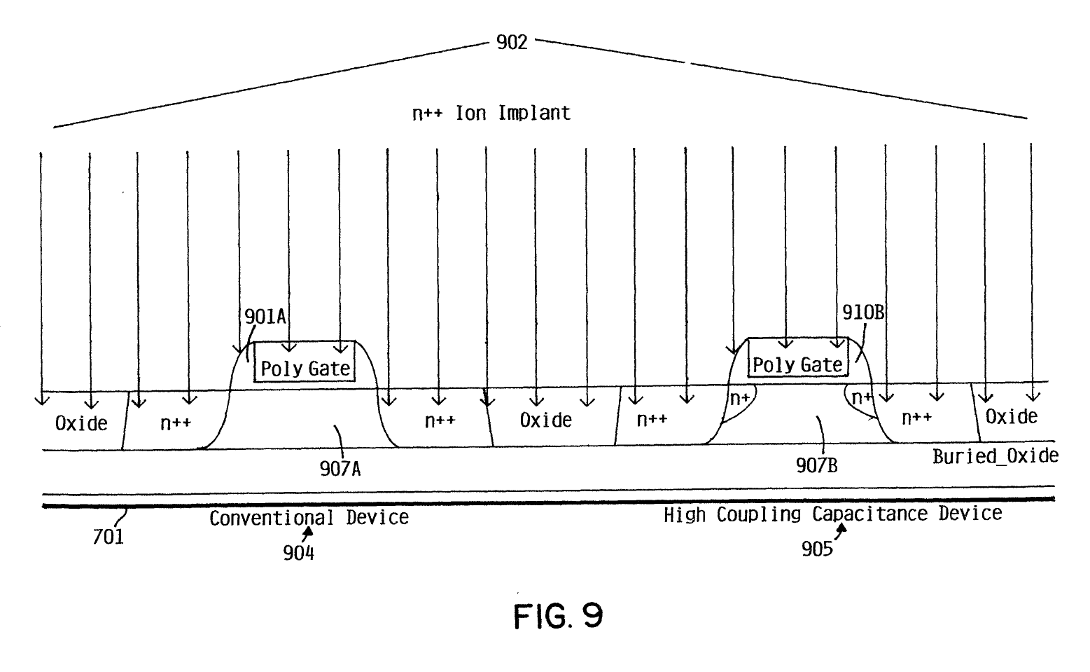

In either case (i.e., for both the processes of FIGS. 7 and 8), a conventional source/drain n++ ion implant 902 is then performed on both the conventional device 904 and the inventive device 905, as shown in FIG. 9. Subsequent to the n++ ion implant 902, the conventional device 904 has a pair of n++ regions on either side of a silicon region 907A which is located primarily under the spacer 910A. Similarly, the inventive device 905 has a pair of n++ regions on either side of a silicon region 907B which is located primarily under the spacer 910B. However, the inventive device 905 also has an n+ region extending into a region under the spacer 910B.

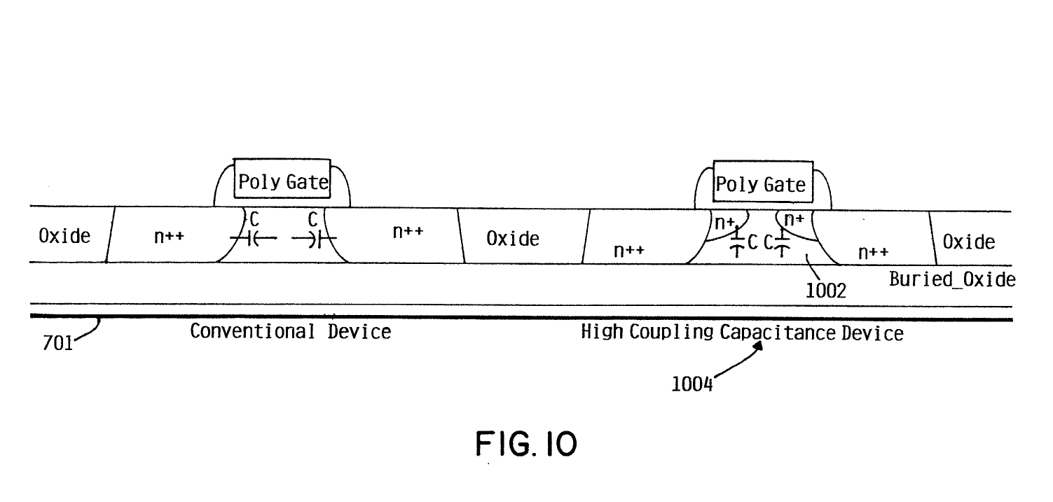

The n+ region is further extended during an annealing step which causes the dopant to out-diffuse. The resulting larger source/drain to body diffusion area 1002 is shown by the high capacitance device 1004 of FIG. 10.

While the foregoing is directed to embodiments of the present invention, other and further embodiments of the invention may be devised without departing from the basic scope thereof, and the scope thereof is determined by the claims that follow.

What is claimed is:

1. A method for reducing parasitic bipolar transistor leakage current in a Silicon on Insulator (SOI) Metal Oxide Semiconductor (MOS) device, comprising:
providing a parasitic bipolar transistor comprising a base terminal, an emitter terminal coupled to a source terminal of the SOI MOS device, and a collector terminal coupled to a drain terminal of the SOI MOS device; and
coupling a capacitor in parallel to the base terminal and emitter terminal of the parasitic bipolar transistor, wherein the capacitor reduces the base to emitter voltage of the parasitic bipolar transistor.

2. The method of claim 1, wherein the capacitor has a capacitance between about 0.5 fF/1 μm and about 4 fF/1 μm.

3. The method of claim 1, wherein the SOI MOS device is a transistor.

4. The method of claim 2, wherein the transistor is selected from one of a n-type field effect transistor (NFET) and a p-type field effect transistor (PFET).

5. The method of claim 1, wherein the capacitor is formed by adding internal capacitance to the SOI MOS device.

6. The method of claim 5, wherein the SOI MOS device is a Field Effect Transistor (FET) and wherein adding the internal capacitance comprises:
masking the device with a photo-resist mask;
performing a shallow ion implant;
removing the photo-resist mask;
depositing a space oxide anisotropically etching the space oxide to create spacers of oxide on the poly-silicon gate side-walls; and
performing a source/drain ion implant.

7. The method of claim 5, wherein the SOI MOS device is a Field Effect Transistor (FET) and wherein adding the internal capacitance comprises:
forming a space oxide;
masking the device with a photo-resist; and
performing an angled ion implant.

8. The method of claim 5, wherein the capacitance is between about 0.5 fF/1 μm and about 4 fF/1 μm.

9. A circuit for reducing parasitic bipolar transistor leakage current in a Silicon on Insulator (SOI) Metal Oxide Semiconductor Field Effect Transistor (FET), comprising:
a capacitor coupled in parallel with a base node and an emitter node of the parasitic bipolar transistor, wherein the capacitor is configured to reduce leakage current generated by the parasitic bipolar transistor.

10. The circuit of claim 9, wherein the FET is selected from one of an n-type field effect transistor (NFET) and a p-type field effect transistor (PFET).

11. The circuit of claim 9, wherein the capacitor comprises a first terminal coupled to the base node of the parasitic bipolar transistor and a second terminal coupled to the emitter node of the parasitic bipolar transistor.

12. The circuit of claim 9, wherein the capacitor is formed by adding internal capacitance to the FET, wherein the capacitance is between about 0.5 fF/1 μm and about 4 fF/1 μm.

13. A circuit, comprising:
a silicon-on-insulator (SOI) metal oxide semiconductor (MOS) field effect transistor (FET) comprising a gate, source and drain terminal;
a parasitic bipolar transistor comprising an emitter terminal coupled to the source terminal of the FET, a collector terminal coupled to the drain terminal of the FET and a base terminal; and
a capacitor comprising a first terminal coupled to the emitter of the parasitic transistor and a second terminal coupled to the base of the parasitic transistor.

14. The circuit of claim 13, wherein the capacitor is configured to reduce leakage current generated by the parasitic bipolar transistor.

15. The circuit of claim 13, wherein the FET is selected from one of an n-type FET and a p-type FET.

16. The circuit of claim 13, wherein the capacitor is formed by adding internal capacitance to the SOI MOS device.

17. The circuit of claim 13, wherein the capacitor has a capacitance between about 0.5 fF/1 μm and about 4 fF/1 μm.
